(19) United States
(12) Patent Application Publication
(10) Pub. No.: US 2015/0098202 A1
(43) Pub. Date: Apr. 9, 2015

(54) EMBEDDED MULTILAYER CERAMIC ELECTRONIC COMPONENT AND PRINTED CIRCUIT BOARD HAVING THE SAME

(71) Applicant: SAMSUNG ELECTRO-MECHANICS CO., LTD., Suwon-Si (KR)

(72) Inventors: Byoung Hwa LEE, Suwon-Si (KR); Hai Joon LEE, Suwon-Si (KR); Eun Hyuk CHAE, Suwon-Si (KR); Bae Gen LEE, Suwon-Si (KR); Jin Man JUNG, Suwon-Si (KR)

(73) Assignee: SAMSUNG ELECTRO-MECHANICS CO., LTD., Suwon-Si (KR)

(21) Appl. No.: 14/269,074

(22) Filed: May 2, 2014

(30) Foreign Application Priority Data
Oct. 8, 2013 (KR) 10-2013-0120074

(51) Int. Cl. H05K 1/02; H05K 1/03; H01G 4/12; H05K 1/18

(52) U.S. Cl. CPC H05K 1/0271; H05K 1/183; H05K 1/0306; H01G 4/12
USPC 361/761

(57) ABSTRACT

A multilayer ceramic electronic component embedded in a board may include: a ceramic body including dielectric layers; a plurality of first and second internal electrodes alternately exposed through both end surfaces of the ceramic body; and first and second external electrodes formed on both end portions of the ceramic body, respectively. The first external electrode may include a first base electrode and a first terminal electrode, the second external electrode may include a second base electrode and a second terminal electrode, 400 nm≦Ra≦600 nm may be satisfied when a surface roughness in a region of 50 μm×50 μm in the first and second terminal electrodes is defined as Ra, and 130 nm≦Ra′≦400 nm may be satisfied when a surface roughness in a region of 10 μm×10 μm in the first and second terminal electrodes is defined as Ra′.

### CROSS-REFERENCE TO RELATED APPLICATION

This application claims the benefit of Korean Patent Application No. 10-2013-0120074 filed on Oct. 8, 2013, with the Korean Intellectual Property Office, the disclosure of which is incorporated herein by reference.

### BACKGROUND

The present disclosure relates to a multilayer ceramic electronic component embedded in a board, and a printed circuit board having the same.

In accordance with an increase in density and integration of electronic circuits, a space in which passive devices are mounted on a printed circuit board has been insufficient. In order to solve this problem, efforts to implement components embedded in boards, for example, embedded devices, have been attempted. Particularly, various methods of embedding a multilayer ceramic electronic component used as a capacitive component in a board have been suggested.

As the method of embedding a multilayer ceramic electronic component in a board, there is a method of using a board material itself as a dielectric material for a multilayer ceramic electronic component and using a copper wiring, or the like, as an electrode for the multilayer ceramic electronic component. In addition, as further methods of implementing a multilayer ceramic electronic component embedded in a board, a method of forming an embedded multilayer ceramic electronic component by forming a high-k polymer sheet or a thin-film dielectric in a board, a method of embedding a multilayer ceramic electronic component in a board, and the like have been used.

In general, the multilayer ceramic electronic component includes a plurality of dielectric layers formed of a ceramic material and internal electrodes disposed between the plurality of dielectric layers. Such a multilayer ceramic electronic component may be disposed in a board to implement a multilayer ceramic electronic component embedded in a board so as to have high capacitance.

In order to manufacture a printed circuit board having the multilayer ceramic electronic component embedded in a board, via holes should be drilled in upper and lower multilayer plates using a laser beam in order to connect board wirings and external electrodes of the multilayer ceramic electronic component to each other, after the multilayer ceramic electronic component is inserted into a core board. This laser processing significantly increases a cost required for manufacturing a printed circuit board.

Meanwhile, since an embedded multilayer ceramic electronic component should be subjected to a process of being embedded in a core part of a board, a nickel/tin (Ni/Sn) plating layer is not required on the external electrode, unlike a general multilayer ceramic electronic component mounted on a surface of the board.

For example, since the external electrode of the multilayer ceramic electronic component embedded in aboard is electrically connected to a circuit in the board through a via of which a material is copper (Cu), a copper (Cu) layer is required to be formed on the external electrode, instead of a nickel/tin (Ni/Sn) layer.

Although the external electrode also generally contains copper (Cu) as a main component, it also contains glass. Therefore, a problem in which a component contained in the glass may absorb a laser beam at the time of performing laser processing to form the via in the board so as not to adjust a depth of the via.

For this reason, a copper (Cu) plating layer has been separately formed on the external electrode of the multilayer ceramic electronic component embedded in a board.

Meanwhile, the embedded multilayer ceramic electronic component may be embedded in a printed circuit board used in a memory card, a personal computer (PC) mainboard, or various radio frequency (RF) modules, thereby significantly decreasing a size of a product as compared with a multilayer ceramic electronic component mounted on a board.

In addition, since the multilayer ceramic electronic component embedded in a board may be disposed to be close to an input terminal of an active device such as a micro processor unit (MPU), it may decrease interconnect inductance caused due to a length of a conducting wire.

However, in a process of embedding the multilayer ceramic electronic component in a board, a heat treatment process for curing an epoxy resin and crystallizing a metal electrode is performed. In this case, a defect on an adhesion surface between the board and the multilayer ceramic electronic component due to a difference in coefficients of thermal expansion (CTE) among the epoxy resin, the metal electrode, a ceramic of the multilayer ceramic electronic component, and the like, or thermal expansion of the board may occur.

This defect may cause delamination of the adhesion surface in a reliability test process.

### SUMMARY

Some embodiments of the present disclosure may provide a multilayer ceramic electronic component embedded in a board, and a printed circuit board having the same.

According to some embodiments of the present disclosure, a multilayer ceramic electronic component embedded in a board may include: a ceramic body including dielectric layers and having first and second main surfaces opposing each other, first and second side surfaces opposing each other, and first and second end surfaces opposing each other; a plurality of first and second internal electrodes alternately exposed through both end surfaces of the ceramic body, having the dielectric layer therebetween; and first and second external electrodes formed on both end portions of the ceramic body, respectively. The first external electrode may include a first base electrode and a first terminal electrode formed on the first base electrode, the second external electrode may include a second base electrode and a second terminal electrode formed on the second base electrode, 400 nm≦Ra≦600 nm may be satisfied when a surface roughness in a region of 50 μm×50 μm in the first and second terminal electrodes is defined as Ra, and 130 nm≦Ra′≦400 nm may be satisfied when a surface roughness in a region of 10 μm×10 μm in the first and second terminal electrodes is defined as Ra′.

The multilayer ceramic electronic component embedded in a board may further include a silane coating layer formed on the ceramic body and the first and second terminal electrodes.

ts≦250 μm may be satisfied when a thickness of the ceramic body is defined as ts.

tp≧5 μm may be satisfied when a thickness of each of the first and second terminal electrodes is defined as tp.

The first and second terminal electrodes may be formed of copper (Cu).

The first and second terminal electrodes may be formed by plating.

According to some embodiments of the present disclosure, a printed circuit board having a multilayer ceramic electronic component embedded therein may include: an insulating substrate; and the multilayer ceramic electronic component embedded in a board including a ceramic body including dielectric layers and having first and second main surfaces opposing each other, first and second side surfaces opposing each other, and first and second end surfaces opposing each other, a plurality of first and second internal electrodes alternately exposed through both end surfaces of the ceramic body, having the dielectric layer therebetween, and first and second external electrodes formed on both end portions of the ceramic body, respectively. The first external electrode may include a first base electrode and a first terminal electrode formed on the first base electrode, the second external electrode may include a second base electrode and a second terminal electrode formed on the second base electrode, 400 nm≦Ra≦600 nm may be satisfied when a surface roughness in a region of 50 μm×50 μm in the first and second terminal electrodes is defined as Ra, and 130 nm≦Ra′≦400 nm may be satisfied when a surface roughness in a region of 10 μm×10 μm in the first and second terminal electrodes is defined as Ra′.

The multilayer ceramic electronic component embedded in a board may further include a silane coating layer formed on the ceramic body and the first and second terminal electrodes.

ts≦250 μm may be satisfied when a thickness of the ceramic body is defined as ts.

tp≧5 μm may be satisfied when a thickness of each of the first and second terminal electrodes is defined as tp.

The first and second terminal electrodes may be made of copper (Cu).

The first and second terminal electrodes may be formed by plating.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view illustrating a multilayer ceramic electronic component embedded in a board according to an exemplary embodiment of the present disclosure;

FIG. 2 is a cross-sectional view taken along line X-X′ of FIG. 1;

FIG. 3 is a schematic plan view of the multilayer ceramic electronic component embedded in a board, as viewed from above in FIG. 1;

FIG. 4 is an enlarged cross-sectional view of region A taken along line Y-Y′ of FIG. 3;

FIG. 5 is an enlarged cross-sectional view of region B taken along line Y-Y′ of FIG. 3; and

FIG. 6 is a cross-sectional view illustrating a printed circuit board having a multilayer ceramic electronic component embedded therein according to an exemplary embodiment of the present disclosure.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

Multilayer Ceramic Electronic Component Embedded in Board

Hereinafter, exemplary embodiments of the present disclosure will be described in detail with reference to the accompanying drawings.

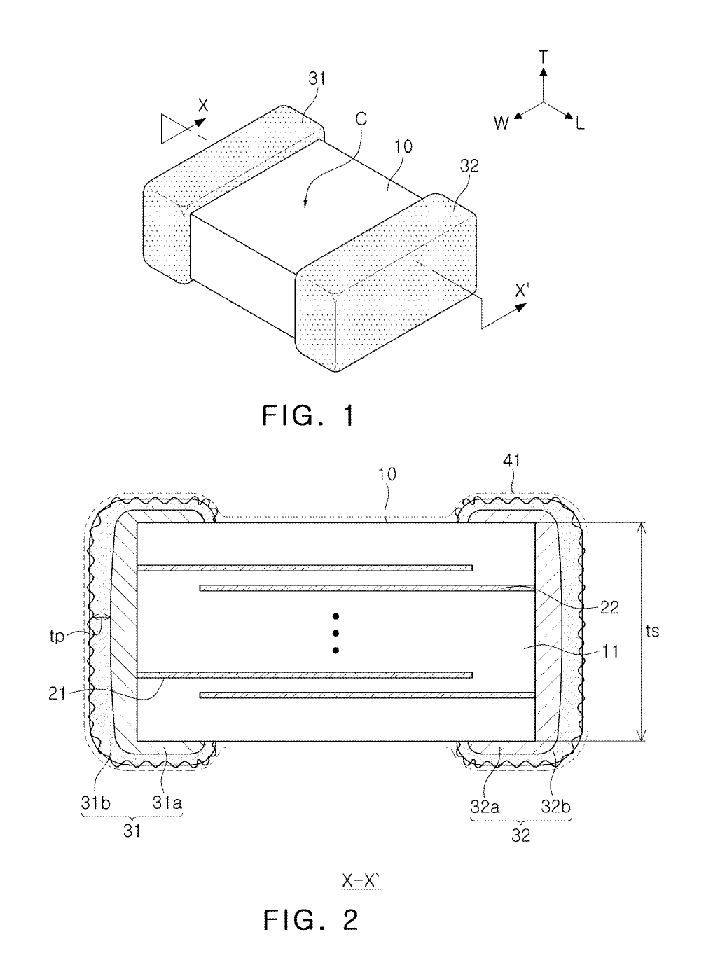

FIG. 1 is a perspective view illustrating a multilayer ceramic electronic component embedded in a board according to an exemplary embodiment of the present disclosure.

FIG. 2 is a cross-sectional view taken along line X-X′ of FIG. 1.

Referring to FIGS. 1 and 2, a multilayer ceramic electronic component embedded in a board according to an exemplary embodiment of the present disclosure may include a ceramic body 10 including dielectric layers 11 and having first and second main surfaces opposing each other, first and second side surfaces opposing each other, and first and second end surfaces opposing each other; a plurality of first and second internal electrodes 21 and 22 alternately exposed through both end surfaces of the ceramic body 10, having the dielectric layer 11 interposed therebetween; and first and second external electrodes 31 and 32 formed on both end portions of the ceramic body 10, respectively. The first external electrode 31 includes a first base electrode 31a and a first terminal electrode 31b formed on the first base electrode 31a, and the second external electrode 32 includes a second base electrode 32a and a second terminal electrode 32b formed on the second base electrode 32a.

Hereinafter, a multilayer ceramic electronic component according to an exemplary embodiment of the present disclosure, in detail, a multilayer ceramic capacitor will be described. However, the present disclosure is not limited thereto.

In the multilayer ceramic capacitor according to an exemplary embodiment of the present disclosure, a ‘length direction’ refers to an ‘L’ direction of FIG. 1, a ‘width direction’ refers to a ‘W’ direction of FIG. 1, and a ‘thickness direction’ refers to a ‘T’ direction of FIG. 1. Here, the ‘thickness direction’ refers to a direction in which the dielectric layers are stacked, for example, a ‘stacking direction’.

In an exemplary embodiment of the present disclosure, a shape of the ceramic body 10 is not particularly limited, but may be a hexahedral shape as shown in FIG. 1.

In an exemplary embodiment of the present disclosure, the ceramic body 10 may have first and second main surfaces opposing each other, first and second side surfaces opposing each other, and first and second end surfaces opposing each other. The first and second main surfaces may also be represented by upper and lower surfaces of the ceramic body 10, respectively.

The ceramic body 10 may have a thickness is of 250 μm or less.

The ceramic body 10 may be manufactured to have the thickness ts of 250 μm or less to be suitable for a multilayer ceramic capacitor embedded in a board.

In addition, the thickness ts of the ceramic body 10 may be a distance between the first and second main surfaces.

According to an exemplary embodiment of the present disclosure, a raw material of the dielectric layer 11 is not particularly limited as long as sufficient capacitance may be obtained therefrom. For example, the raw material of the dielectric layer 11 may be a barium titanate (BaTiO₃) powder.

A material of the dielectric layer 11 may be prepared by adding various ceramic additives, organic solvents, plasticizers, binders, dispersing agents, and the like, to a powder such as the barium titanate (BaTiO₃) powder, or the like, according to an exemplary embodiment of the present disclosure.

An average particle size of ceramic powder particles used to form the dielectric layer 11 is not particularly limited, but may be controlled to implement an exemplary embodiment of the present disclosure. For example, the average particle size of the ceramic powder particles used to form the dielectric layer 11 may be controlled to be 400 nm or less.

The ceramic body 10 may include an active layer, contributing to the formation of capacitance of the capacitor, and upper and lower cover layers formed as upper and lower margins parts on and below the active layer, respectively.

The active layer may be formed by repeatedly stacking the plurality of first and second internal electrodes 21 and 22 to have the dielectric layers 11 therebetween.

The upper and lower cover layers may be formed of the same material as that of the dielectric layer 11 and have the same configuration as that of the dielectric layer 11 except that they do not include the internal electrodes.

The upper and lower cover layers may be formed by stacking one dielectric layer or two or more dielectric layers on upper and lower surfaces of the active layers, respectively, in a thickness direction, and may basically serve to prevent damage to the internal electrodes due to physical or chemical stress.

Meanwhile, the first and second internal electrodes 21 and 22, a pair of electrodes having different polarities, may be formed by printing a conductive paste including a conductive metal to a predetermined thickness on the dielectric layer 11.

In addition, the first and second internal electrodes 21 and 22 may be formed in the stacking direction of the dielectric layers 11 so as to be alternately exposed through both end surfaces of the ceramic body 10, and may be electrically insulated from each other by the dielectric layer 11 interposed therebetween.

For example, the first and second internal electrodes 21 and 22 may be electrically connected to first and second external electrodes 31 and 32, respectively, through portions of the first and second internal electrodes alternately exposed through both end surfaces of the ceramic body 10.

Therefore, when a voltage is applied to the first and second external electrodes 31 and 32, electric charges may be accumulated between the first and second internal electrodes 21 and 22 facing each other. In this case, capacitance of the multilayer ceramic capacitor may be in proportion to an area of a region in which the first and second internal electrodes 21 and 22 are overlapped with each other.

In addition, the conductive metal contained in the conductive paste forming the first and second internal electrodes 21 and 22 may be nickel (Ni), copper (Cu), palladium (Pd), or an alloy thereof. However, the present disclosure is not limited thereto.

In addition, as a method of printing the conductive paste, a screen printing method, a gravure printing method, or the like, may be used. However, the present disclosure is not limited thereto.

According to an exemplary embodiment of the present disclosure, the ceramic body 10 may have the first and second external electrodes 31 and 32 formed on both end portions thereof.

The first external electrode 31 may include the first base electrode 31a electrically connected to the first internal electrodes 21 and the first terminal electrode 31b formed on the first base electrode 31a.

The second external electrode 32 may include the second base electrode 32a electrically connected to the second internal electrodes 22 and the second terminal electrode 32b formed on the second base electrode 32a.

Hereinafter, structures of the first and second external electrodes 31 and 32 will be described in further detail.

The first and second base electrodes 31a and 32a may contain a first conductive metal and glass.

The first and second external electrodes 31 and 32 may be formed on both end surfaces of the ceramic body 10, respectively, in order to form capacitance, and the first and second base electrodes 31a and 32a included in the first and second external electrodes 31 and 32 may be electrically connected to the first and second internal electrodes 21 and 22, respectively.

The first and second base electrodes 31a and 32a may be formed of the same conductive material as that of the first and second internal electrodes 21 and 22, but are not limited thereto. For example, the first and second base electrodes 31a and 32a may be made of one or more first conductive metals selected from a group consisting of copper (Cu), silver (Ag), nickel (Ni), and alloys thereof.

The first and second base electrodes 31a and 32a may be formed by applying and then sintering a conductive paste prepared by adding glass frit to powder particles of the first conductive metal.

According to an exemplary embodiment of the present disclosure, the first and second external electrodes 31 and 32 may include the first and second terminal electrodes 31b and 32b formed on the first and second base electrodes 31a and 32a, respectively.

The first and second terminal electrodes 31b and 32b may be made of a second conductive material.

The second conductive metal is not particularly limited, but may be, for example, copper (Cu).

Generally, since the multilayer ceramic capacitor is mounted on a printed circuit board, a nickel/tin plating layer may be usually formed on the external electrode.

However, the multilayer ceramic capacitor embedded in a printed circuit board according to an exemplary embodiment of the present disclosure is not mounted on the board, and the first and second external electrodes 31 and 32 of the multilayer ceramic capacitor and a circuit of the board may be electrically connected to each other through vias of which a material is copper (Cu).

Therefore, according to an exemplary embodiment of the present disclosure, the first and second terminal electrodes 31b and 32b may be formed of copper (Cu) so as to have good electrical connectivity with the copper (Cu), a material of the via formed in the board.

Meanwhile, although the first and second base electrodes 31a and 32a contain copper (Cu) as a main component, glass may also be contained therein. Therefore, there may be a problem in which a component contained in the glass absorbs a laser beam at the time of performing laser processing in order to form a via in the board, such that a depth of the via may not be adjusted.

For this reason, the first and second terminal electrodes 31b and 32b of the multilayer ceramic electronic component embedded in a board may be formed of copper (Cu).

A method of forming the first and second terminal electrodes 31b and 32b is not particularly limited, but may be, for example, a plating method.

Therefore, the first and second terminal electrodes 31b and 32b after being sintered may only be formed of copper (Cu) without containing glass frit therein. Accordingly, a problem in which a component contained in the glass absorbs a laser beam at the time of performing the laser processing to form the via in the board, such that a depth of the via may not be controlled, does not occur.

When a thickness of each of the first and second terminal electrodes 31b and 32b is defined as tp, tp5um may be satisfied.

The thickness tp of each of the first and second terminal electrodes 31b and 32b may be equal to or larger than 5 μm, but is not limited thereto. For example, the thickness tp of each of the first and second terminal electrodes 31b and 32b may be 15 μm or less.

The thickness tp of each of the first and second terminal electrodes 31b and 32b is controlled to be equal to or larger than 5 μm and be 15 μm or less, whereby a multilayer ceramic capacitor capable of providing excellent via drilling in the board and having excellent reliability may be implemented.

In the case in which the thickness tp of each of the first and second terminal electrodes 31b and 32b is less than 5 μm, a defect in which a conductive via hole is formed to the surface of the ceramic body 10 when the multilayer ceramic electronic component is embedded within the printed circuit board and the via is drilled may occur as described below.

In the case in which the thickness tp of each of the first and second terminal electrodes 31b and 32b exceeds 15 μm, cracks may occur in the ceramic body 10 due to stress of the first and second terminal electrodes 31b and 32b.

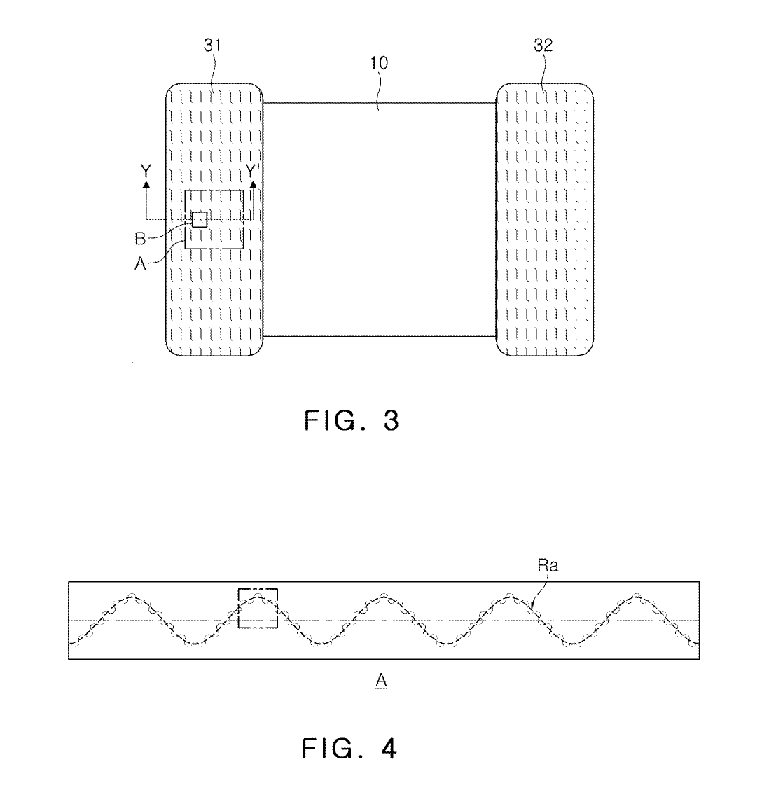

FIG. 3 is a schematic plan view of the multilayer ceramic electronic component embedded in a board, as viewed above in FIG. 1.

FIG. 4 is an enlarged cross-sectional view of region A taken along line Y-Y′ of FIG. 3.

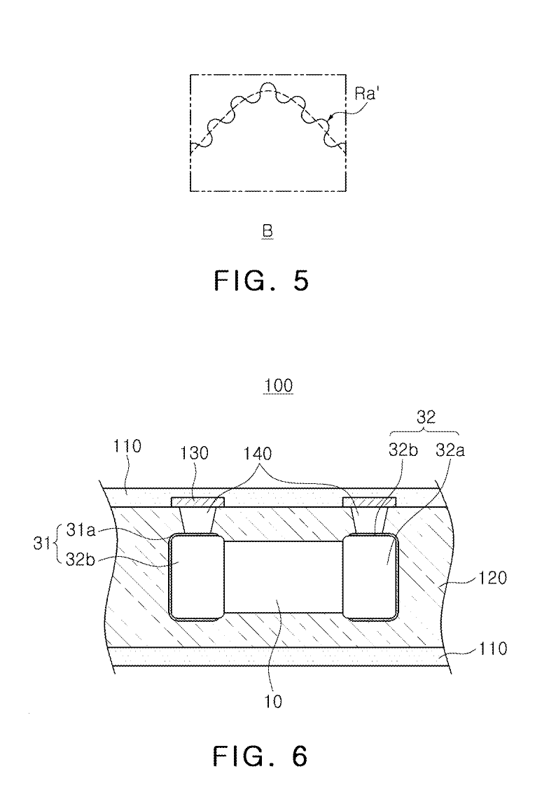

FIG. 5 is an enlarged cross-sectional view of region B taken along line Y-Y′ of FIG. 3.

Referring to FIGS. 3 through 5, in the multilayer ceramic electronic component according to an exemplary embodiment of the present disclosure, when a surface roughness in a region of 50 μm×50 μm in the first and second terminal electrodes 31b and 32b is defined as Ra, 400 nm≦Ra≦600 nm may be satisfied, and when a surface roughness in a region of 10 μm×10 μm in the first and second terminal electrodes 31b and 32b is defined as Ra′, 130 nm≦Ra′≦400 nm may be satisfied.

Referring to FIG. 4, the surface roughness Ra in the region of 50 μm×50 μm in the first and second terminal electrodes 31b and 32b may be in a range of 400 nm to 600 nm (400 nm≦Ra≦600 nm).

The surface roughness Ra in the region of 50 μm×50 μm in the first and second terminal electrodes 31b and 32b is controlled to be in the range of 400 nm to 600 nm (400 nm≦Ra≦600 nm), whereby a delamination phenomenon between the multilayer ceramic electronic component and the board may be decreased and cracks may be prevented.

The surface roughness indicates a difference in a degree of magnitude of fine prominences-depressions generated on a metal surface when the metal surface is processed.

The surface roughness may be generated by a tool used for processing the metal surface, depending on whether or not such a processing method is appropriate, scratches generated in the metal surface, rust, and the like. In providing a degree of roughness, a cross section of a surface taken by cutting the surface on a plane perpendicular to the surface may be formed to have a curved line shape, and a height from the lowest portion of this curved line to the highest portion thereof may be known as a center line average roughness and be represented by Ra.

In the present disclosure, a center line average roughness or a surface roughness of the first and second terminal electrode 31b or 32b in the region of 50 μm×50 μm in the first and second terminal electrodes 31b and 32b will be defined as Ra.

The surface roughness may be recognized from the cross section of the surface taken by cutting the surface on a plane perpendicular to the surface may be formed in a shape of a curved line, and it may be appreciated that the surface roughness forms a large wavy line as represented by a dotted line in FIG. 4.

In detail, a method of calculating the surface roughness Ra of each of the first and second terminal electrodes 31b and 32b in the region of 50 μm×50 μm in the first and second terminal electrodes 31b and 32b will be described below. First, a virtual center line may be drawn with respect to a roughness formed in the region of 50 μm×50 μm on one surface of the first or second terminal electrodes 31b or 32b, as shown in FIGS. 3 and 4.

Next, the respective distances (for example, r₁, r₂, r₃ . . . r₁₃) to the highest portions of respective waves represented by the dotted line, based on the virtual center line of the roughness, may be measured, an average value of the respective distances may be calculated as represented by the following

Equation, and the surface roughness Ra of the first and second terminal electrodes 31b and 32b may be calculated by the calculated average value.

$${R}_{a} = \frac{\vert {r}_{1} \vert + \vert {r}_{2} \vert + \vert {r}_{3} \vert + … \vert {r}_{n} \vert}{n}$$

The surface roughness Ra in the region of 50 μm×50 μm in the first and second terminal electrodes 31b and 32b is controlled to be in the range of 400 nm to 600 nm (400 nm≦Ra≦600 nm), whereby a multilayer ceramic electronic component having improved adhesion with the board and having excellent reliability may be implemented.

In the case in which the surface roughness Ra in the region of 50 μm×50 μm in the first and second terminal electrodes 31b and 32b is less than 400 nm, a delamination phenomenon between the multilayer ceramic electronic component and the board may occur.

On the other hand, in the case in which the surface roughness Ra in the region of 50 μm×50 μm in the first and second terminal electrodes 31b and 32b exceeds 600 nm, cracks may occur.

A method of controlling the surface roughness Ra in the region of 50 μm×50 μm in the first and second terminal electrodes 31b and 32b so as to be in the range of 400 nm to 600 nm (400 nm≦Ra≦600 nm) may be performed by using sandpaper or by a physical method such as plasma treatment, or the like, in a process of manufacturing the multilayer ceramic capacitor.

For example, in the case of using the sandpaper, when sandpaper having a value of P that is in a range of 100 to 3000 is used, a roughness may be artificially formed, and only a partial roughness may be increased on the surface of the respective first and second terminal electrodes 31b and 32b, thereby forming the surface roughness of the respective first and second terminal electrodes 31b and 32b without affecting reliability of the multilayer ceramic electronic component.

‘P’ of the sandpaper is a sign indicating a standard of a particle size of Federation of European Producers of Abrasives (FEPA).

Referring to FIG. 5, when the surface roughness in the region of 10 μm×10 μm in the first and second terminal electrodes 31b and 32b is Ra′, 130 nm≦Ra′≦400 nm may be satisfied.

The surface roughness Ra′ in the region of 10 μm×10 μm in the first and second terminal electrodes 31b and 32b is controlled to be in the range of 130 nm to 400 nm (130 nm≦Ra′≦400 nm), whereby a delamination phenomenon between the multilayer ceramic electronic component and the board may be further effectively decreased.

The surface roughness has been defined above with reference to FIGS. 4 and 5, and in the present disclosure, a center line average roughness or a surface roughness of each of the first and second terminal electrodes 31b and 32b in the region of 10 μm×10 μm in the first and second terminal electrodes 31b and 32b will be defined as Ra′.

The surface roughness may be recognized from a cross section of the surface taken by cutting the surface on a plane perpendicular to the surface, and it may be appreciated that the surface roughness forms a small wavy line as represented by a solid line in FIGS. 4 and 5.

In detail, a method of calculating the surface roughness Ra′ of the first or second terminal electrodes 31b or 32b in the region of 10 μm×10 μm in the first or second terminal electrodes 31b or 32b will be described below. First, a virtual center line may be drawn with respect to a roughness formed in the region of 10 μm×10 μm on one surface of each of the first and second terminal electrodes 31b and 32b, as shown in FIGS. 3 and 5.

Next, the respective distances (for example, r₁′, r₂′, r₃′ . . . r₁₃′) to the highest portions of respective curves represented by a solid line, based on the virtual center line of the roughness, may be measured, an average value of the respective distances may be calculated as represented by the following Equation, and the surface roughness Ra′ of the first and second terminal electrodes 31b and 32b may be calculated using the calculated average value.

$${Ra}^{′} = \frac{\vert {r}_{1}^{′} \vert + \vert {r}_{2}^{′} \vert + \vert {r}_{3}^{′} \vert + … \vert {r}_{n}^{′} \vert}{n}$$

The surface roughness Ra′ in the region of 10 μm×10 μm in the first and second terminal electrodes 31b and 32b is controlled to be in the range of 130 nm to 400 nm (130 nm≦Ra≦′≦400 nm), whereby a multilayer ceramic electronic component having improved adhesion with the board and having excellent reliability may be implemented.

In the case in which the surface roughness Ra′ in the region of 10 μm×10 μm in the first and second terminal electrodes 31b and 32b is less than 130 nm, an improvement effect of adhesion between the multilayer ceramic electronic component and the board may not be present.

On the other hand, in the case in which the surface roughness Ra′ in the region of 10 μm×10 μm in the first and second terminal electrodes 31b and 32b exceeds 400 nm, cracks may occur.

A method of controlling the surface roughness Ra′ in the region of 10 μm×10 μm in the first and second terminal electrodes 31b and 32b so as to be in the range of 130 nm to 400 nm (130 nm≦Ra′≦400 nm) may be performed by immersing a ceramic body having external electrodes formed thereon in an etchant and then rotating the ceramic body, in a process of manufacturing the multilayer ceramic capacitor.

For example, the method of forming the surface roughness may be performed by chemical treatment, unlike the above-described physical method for forming the surface roughness Ra in the region of 50 μm×50 μm in the first and second terminal electrodes 31b and 32b.

The roughness may be artificially formed by the chemical method of immersing the ceramic body having the external electrodes formed thereon in the etchant, such that the roughness may be more finely formed as compared with the physical method.

Therefore, the surface roughness Ra′ of each of the first and second terminal electrodes 31b and 32b may be formed so that the surface roughness Ra′ in the region of 10 μm×10 μm in the first and second terminal electrodes 31b and 32b is in the range of 130 nm to 400 nm (130 nm≦Ra′≦400 nm).

An etchant dissolving only copper (Cu) may be used as the etchant, whereby the surface roughness Ra′ of the respective first and second terminal electrodes 31b and 32b may be finely formed without having an effect on reliability of the multilayer ceramic electronic component.

Meanwhile, according to an exemplary embodiment of the present disclosure, a silane coating layer 41 may be formed on the ceramic body 10 and the first and second terminal electrodes 31b and 32b.

The silane coating layer 41 is formed on the ceramic body 10 and the first and second terminal electrodes 31b and 32b, whereby a multilayer ceramic electronic component having improved adhesion with the board and having excellent reliability may be implemented.

The silane coating layer 41 is not particularly limited as long as it contains silicon. For example, the silane coating layer 41 may have a form in which silicon is used as a central atom, an epoxy group is bonded to one end of the silicon coating layer, and an alkyl group is bonded to the other end of the silicon coating layer.

Hereinafter, a method of manufacturing a multilayer ceramic electronic component embedded in a board according to an exemplary embodiment of the present disclosure will be described. However, the present disclosure is not limited thereto.

In the method of manufacturing a multilayer ceramic electronic component embedded in a board according to an exemplary embodiment of the present disclosure, a slurry containing powder particles such as barium titanate (BaTiO₃) powder particles, or the like, may be first applied to and dried on a carrier film to prepare a plurality of ceramic green sheets, thereby forming dielectric layers.

The ceramic green sheet may be manufactured by preparing a slurry by mixing ceramic powder particles, a binder, and a solvent with each other and forming the slurry as a sheet having a thickness of several μm by a doctor blade method.

Next, a conductive paste for an internal electrode containing 40 to 50 parts by weight of nickel powder particles having an average particle size of 0.1 to 0.2 μm may be prepared.

The conductive paste for an internal electrode may be applied to the ceramic green sheet by a screen printing method to form the internal electrode, and four hundreds to five hundreds of ceramic green sheets may be stacked to manufacture the ceramic body 10.

In the multilayer ceramic capacitor according to an exemplary embodiment of the present disclosure, the first and second internal electrodes 21 and 22 may be exposed to both end surfaces of the ceramic body 10, respectively.

Next, the first and second base electrodes containing the first conductive metal and glass may be formed on the end portions of the ceramic body 10.

The first conductive metal is not particularly limited, but may be, for example, one or more selected from a group consisting of copper (Cu), silver (Ag), nickel (Ni), and alloys thereof.

The glass is not particularly limited, but may be a material having the same composition as that of glass used to manufacture an external electrode of a general multilayer ceramic capacitor.

The first and second base electrodes may be formed on the end portions of the ceramic body to be electrically connected to the first and second internal electrodes, respectively.

Then, a plating layer made of the second conductive metal may be formed on the first and second base electrodes.

The second conductive metal is not particularly limited, but may be, for example, copper (Cu).

The plating layers may be formed as the first and second terminal electrodes.

A relatively large surface roughness may be formed on the respective first and second terminal electrodes by the sandpaper or the plasma treatment, and a fine surface roughness may be formed on the first and second terminal electrodes by immersing the first and second terminal electrodes on which the large surface roughness is formed in the etchant.

A description of portions having the same features as those of the multilayer ceramic electronic component embedded in a board according to the foregoing exemplary embodiment of the present disclosure will be omitted.

Hereinafter, although the present disclosure will be described in more detail with reference to Inventive Example, the present disclosure is not limited thereto.

### INVENTIVE EXAMPLE 1

In order to confirm whether or not a via drilling defect has occurred depending on a thickness of first and second terminal electrodes 31b and 32b of a multilayer ceramic electronic component embedded in a board according to Inventive Example and occurrence frequency of delamination on an adhesion surface depending on a surface roughness Ra in a region of 50 μm×50 μm in the first and second terminal electrodes and a surface roughness Ra′ in a region of 10 μm×10 μm in the first and second terminal electrodes, each experiment was performed on a board in which the multilayer ceramic electronic component is embedded.

The following Table 1 shows whether or not a via drilling defect has occurred depending on a thickness of the first and second terminal electrodes 31b and 32b.

TABLE 1

| Thickness (μm) of Each of First and | |
|---|---|
| Second Terminal Electrodes | Decision |
| less than 1 | X |
| 1 to 2 | X |
| 2 to 3 | X |
| 3 to 4 | Δ |
| 4 to 5 | ◯ |
| 5 to 6 | ⊚ |
| 6 or more | ⊚ |

X: defective rate of 50% or more
Δ: defective rate of 10 to 50%
◯: defective rate of 0.01 to 10%
⊚: defective rate less than 0.01%

Referring to Table 1, it may be appreciated that in the case in which the thickness of each of the first and second terminal electrodes 31b and 32b is 5 μm or more, a multilayer ceramic capacitor capable of allowing for excellent via drilling in the board and having excellent reliability may be implemented.

On the other hand, it may be appreciated that in the case in which the thickness of each of the first and second terminal electrodes 31b and 32b is less than 5 μm, a detect may occur at the time of drilling the vias in the board.

The following Table 2 shows the occurrence frequency of delamination on an adhesion surface depending on the surface roughness Ra in the region of 50 μm×50 μm in the first and second terminal electrodes.

TABLE 2

| Surface Roughness Ra (nm) in Region of | |
|---|---|
| 50 μm × 50 μm in First and Second | |
| terminal Electrodes | Decision |
| less than 400 | X |
| 400 | ◯ |
| 460 | ◯ |
| 520 | ⊚ |
| 600 | ⊚ |
| 600 or more | ⊚ |

X: defective rate of 50% or more
Δ: defective rate of 10 to 50%
◯: defective rate of 0.01 to 10%
⊚: defective rate less than 0.01%

Referring to Table 2, it may be appreciated that in the case in which the surface roughness of each of the first and second terminal electrodes 31b and 32b is 400 nm or more, the occurrence frequency of delamination on an adhesion surface is relatively low, such that a multilayer ceramic capacitor having excellent reliability may be implemented.

On the other hand, it may be appreciated that in the case in which the surface roughness of each of the first and second terminal electrodes 31b and 32b is less than 400 nm, the occurrence frequency of delamination on the adhesion surface is increased, such that reliability of the multilayer ceramic capacitor is decreased.

The following Table 3 shows the occurrence frequency of delamination on an adhesion surface depending on the surface roughness Ra′ in the region of 10 μm×10 μm in the first and second terminal electrodes.

TABLE 3

| Surface Roughness Ra′ (nm) in Region of | |
|---|---|
| 10 μm × 10 μm in First and Second | |
| terminal Electrodes | Decision |
| less than 130 | X |
| 130 | ◯ |
| 150 | ◯ |
| 200 | ⊚ |
| 300 | ⊚ |
| 400 or more | ⊚ |

X: defective rate of 50% or more
Δ: defective rate of 10 to 50%
◯: defective rate of 0.01 to 10%
⊚: defective rate less than 0.01%

Referring to Table 3, it may be appreciated that in the case in which the surface roughness of each of the first and second terminal electrodes 31b and 32b is 130 nm or more, the occurrence frequency of delamination on the adhesion surface is relatively low, such that a multilayer ceramic capacitor having excellent reliability may be implemented.

On the other hand, it may be appreciated that in the case in which the surface roughness of each of the first and second terminal electrodes 31b and 32b is less than 130 nm, an improvement effect of adhesion between the multilayer ceramic electronic component and the board is not present.

Printed Circuit Board Having Multilayer Ceramic Electronic Component Embedded Therein

FIG. 6 is a cross-sectional view illustrating a printed circuit board having a multilayer ceramic electronic component embedded therein according to an exemplary embodiment of the present disclosure.

Referring to FIG. 6, a printed circuit board 100 having a multilayer ceramic electronic component embedded therein according to an exemplary embodiment of the present disclosure may include an insulating substrate 110; and the multilayer ceramic electronic component embedded in a board including a ceramic body 10 including dielectric layers 11 and having first and second main surfaces opposing each other, first and second side surfaces opposing each other, and first and second end surfaces opposing each other, a plurality of first and second internal electrodes 21 and 22 alternately exposed through both end surfaces of the ceramic body 10, respectively, having the dielectric layers 11 therebetween, and first and second external electrodes 31 and 32 formed on both end portions of the ceramic body 10, respectively. The first external electrode 31 includes a first base electrode 31a and a first terminal electrode 31b formed on the first base electrode 31a. The second external electrode 32 includes a second base electrode 32a and a second terminal electrode 32b formed on the second base electrode 32a. Here, 400 nm≦Ra≦600 nm may be satisfied when a surface roughness in a region of 50 μm×50 μm in the first and second terminal electrodes 31b and 32b is Ra, and 130 nm≦Ra′≦400 nm may be satisfied when a surface roughness in a region of 10 μm×10 μm in the first and second terminal electrodes 31b and 32b is defined as Ra′.

The insulating substrate 110 may have a structure in which it includes an insulating layer 120 and may include conductive patterns 130 and conductive via holes 140, configuring interlayer circuits in various forms as shown in FIG. 6 if necessary. The insulating substrate 110 may be the printed circuit board 100 including the multilayer ceramic electronic component disposed therein.

After the multilayer ceramic electronic component is inserted into the printed circuit board 100, it may be subjected to several severe environments when a post-process such as a heat treating process, and the like, is performed on the printed circuit board 100.

In further detail, in the heat treating process, contraction and expansion of the printed circuit board 100 may be directly transferred to the multilayer ceramic electronic component inserted into the printed circuit board 100 to apply stress to an adhesion surface between the multilayer ceramic electronic component and the printed circuit board 100.

In the case in which the stress applied to the adhesion surface between the multilayer ceramic electronic component and the printed circuit board 100 is higher than adhesion strength therebetween, a delamination defect that the adhesion surface is delaminated may occur.

The adhesion strength between the multilayer ceramic electronic component and the printed circuit board 100 may be in proportion to electrochemical coupling force between the multilayer ceramic electronic component and the printed circuit board 100 and an effective surface area of the adhesion surface between the multilayer ceramic electronic component and the printed circuit board 100. Therefore, the surface roughness of the multilayer ceramic electronic component is controlled to increase the effective surface area of the adhesion surface between the multilayer ceramic electronic component and the printed circuit board 100, whereby the delamination phenomenon between the multilayer ceramic electronic component and the printed circuit board 100 may be decreased.

In addition, the occurrence frequency of the delamination of the adhesion surface between the multilayer ceramic electronic component and the printed circuit board 100 depending on the surface roughness of the multilayer ceramic electronic component embedded in the printed circuit board 100 may be confirmed.

For example, the surface roughness Ra in the region of 50 μm×50 μm in the first and second terminal electrodes 31b and 32b is controlled to be in the range of 400 to 600 nm (400 nm≦Ra≦600 nm) and the surface roughness Ra′ in the region of 10 μm×10 μm in the first and second terminal electrodes 31b and 32b is controlled to be in the range of 130 to 400 nm (130 nm≦Ra′≦400 nm), whereby an adhesion property between the multilayer ceramic electronic component and the board may be improved to decrease the occurrence of delamination phenomenon between the multilayer ceramic electronic component and the board.

Since other features are the same as those of the printed circuit board having a multilayer ceramic electronic component embedded therein according to the foregoing exemplary embodiment of the present disclosure described above, a description thereof will be omitted.

According to exemplary embodiments of the present disclosure, a surface treatment is performed on the multilayer ceramic electronic component embedded in a board and the surface roughness of an upper plating layer of a respective external electrode of the multilayer ceramic electronic component embedded in a board is controlled, whereby an adhesion property between the multilayer ceramic electronic component and the board may be improved to decrease a delamination phenomenon between a multilayer ceramic electronic component and a board.

While exemplary embodiments have been shown and described above, it will be apparent to those skilled in the art that modifications and variations could be made without departing from the spirit and scope of the present disclosure as defined by the appended claims.

What is claimed is:

1. A multilayer ceramic electronic component embedded in a board, comprising:
a ceramic body including dielectric layers, first and second main surfaces opposing each other, first and second side surfaces opposing each other, and first and second end surfaces opposing each other;
a plurality of first and second internal electrodes alternately exposed through end surfaces of the ceramic body, the dielectric layers being disposed between the plurality of first and second internal electrodes; and
first and second external electrodes disposed on end portions of the ceramic body, respectively,
wherein the first external electrode includes a first base electrode and a first terminal electrode disposed on the first base electrode, the second external electrode includes a second base electrode and a second terminal electrode disposed on the second base electrode, 400 nm≦Ra≦600 nm is satisfied when a surface roughness in a region of 50 μm×50 μm in the first and second terminal electrodes is defined as Ra, and 130 nm≦Ra′≦400 nm is satisfied when a surface roughness in a region of 10 μm×10 μm in the first and second terminal electrodes is defined as Ra′.

2. The multilayer ceramic electronic component embedded in a board of claim 1, further comprising a silane coating layer formed on the ceramic body and the first and second terminal electrodes.

3. The multilayer ceramic electronic component embedded in a board of claim 1, wherein when a thickness of the ceramic body is defined as ts, ts≦250 μm is satisfied.

4. The multilayer ceramic electronic component embedded in a board of claim 1, wherein when a thickness of each of the first and second terminal electrodes is defined as tp tp≧5 μm is satisfied.

5. The multilayer ceramic electronic component embedded in a board of claim 1, wherein the first and second terminal electrodes are formed of copper (Cu).

6. The multilayer ceramic electronic component embedded in a board of claim 1, wherein the first and second terminal electrodes are formed by plating.

7. A printed circuit board having a multilayer ceramic electronic component embedded therein, comprising:
an insulating substrate; and
the multilayer ceramic electronic component embedded in a board including a ceramic body including dielectric layers and having first and second main surfaces opposing each other, first and second side surfaces opposing each other, and first and second end surfaces opposing each other, a plurality of first and second internal electrodes alternately exposed through both end surfaces of the ceramic body, having the dielectric layer therebetween, and first and second external electrodes formed on both end portions of the ceramic body, respectively,
wherein the first external electrode includes a first base electrode and a first terminal electrode formed on the first base electrode, the second external electrode includes a second base electrode and a second terminal electrode formed on the second base electrode, 400 nm≦Ra≦600 nm is satisfied when a surface roughness in a region of 50 μm×50 μm in the first and second terminal electrodes is defined as Ra, and 130 nm≦Ra′≦400 nm is satisfied when a surface roughness in a region of 10 μm×10 μm in the first and second terminal electrodes is defined as Ra′.

8. The printed circuit board having a multilayer ceramic electronic component embedded therein of claim 7, wherein the multilayer ceramic electronic component embedded in a board further includes a silane coating layer formed on the ceramic body and the first and second terminal electrodes.

9. The printed circuit board having a multilayer ceramic electronic component embedded therein of claim 7, wherein when a thickness of the ceramic body is defined as ts, ts≦250 μm is satisfied.

10. The printed circuit board having a multilayer ceramic electronic component embedded therein of claim 7, wherein when a thickness of each of the first and second terminal electrodes is defined as tp, tp≧5 μm is satisfied.

11. The printed circuit board having a multilayer ceramic electronic component embedded therein of claim 7, wherein the first and second terminal electrodes are made of copper (Cu).

12. The printed circuit board having a multilayer ceramic electronic component embedded therein of claim 7, wherein the first and second terminal electrodes are formed by plating.
